(19) United States
(12) Patent Application Publication
(10) Pub. No.: US 2023/0157173 A1
(43) Pub. Date: May 18, 2023

(54) THERMOELECTRIC MODULE PROTECTION CIRCUIT AND THERMOELECTRIC DEVICE COMPRISING SAME

(71) Applicant: TEGWAY CO.,LTD, Daejeon (KR)

(72) Inventor: Ockkyun OH, Daejeon (KR)

(73) Assignee: TEGWAY CO.,LTD, Daejeon (KR)

(21) Appl. No.: 17/917,914

(22) PCT Filed: Jan. 21, 2021
(86) PCT No.: PCT/KR2021/000818

§ 371 Date: Oct. 7, 2022

(30) Foreign Application Priority Data
May 29, 2020 (KR) 10-2020-0064982

(51) Int. Cl. H10N 10/17; H10N 19/00; G01R 31/26

(52) U.S. Cl. CPC H10N 10/17; H10N 19/00; G01R 31/2637

(57) ABSTRACT

The present specification relates to a thermoelectric module protection circuit and a thermoelectric device including the same, and According to one aspect of the present specification, there is provided a thermoelectric device including: a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, a power supply unit configured to output a predetermined current applied to the thermoelectric module to cause the thermoelectric module to perform a thermoelectric operation including an endothermic operation and an exothermic operation so that the thermal stimulus is provided through the first surface, a voltage monitoring unit configured to monitor an output voltage of the thermoelectric module, wherein the output voltage reflects a temperature difference between the first surface and the second surface, a voltage comparison unit configured to compare the output voltage and a reference voltage, and output an application control signal which instructs whether to apply power to the thermoelectric module to stop supplying the power to the thermoelectric module when the temperature difference is greater than or equal to a threshold value, and a power controller configured to adjust whether to apply the power to the thermoelectric module based on the application control signal.

### TECHNICAL FIELD

The present specification relates to a thermoelectric module protection circuit and a thermoelectric device including the same, and more specifically, to a thermoelectric device configured to detect damage of a thermoelectric module or prevent a malfunction of the thermoelectric module using a thermoelectric module protection circuit.

### BACKGROUND ART

A thermoelectric element (TE) is an element which causes an exothermic reaction or an endothermic reaction by receiving electrical energy due to the Peltier effect, and is used to provide thermal stimuli such as a feeling of warmth, a feeling of coldness, a thermal grill illusion, and the like to a user.

Generally, a thermoelectric module including a thermoelectric element comes into contact with a user's skin to provide a thermal stimulus to the user. However, when thermoelectric module is used, damage such as cracks or the like can occur between the thermoelectric element and an electrode, and in this case, a temperature of the damaged area locally increases, resulting in burns to the user. Further, a thermoelectric module can be suddenly driven when a user is not using the thermoelectric module, such as when the user is not wearing the thermoelectric module or the like, and in this case, there is a risk of fire and burning. In addition, even when a user is using a thermoelectric module, as the thermoelectric module is not controlled in a state of maximum output thereof due to an unexpected situation, there is a risk of causing burns to the user.

### DISCLOSURE

### Technical Problem

The present specification is directed to providing a thermoelectric device including a thermoelectric module protection circuit which detects damage of a thermoelectric module or prevents a malfunction of the thermoelectric module.

The present specification is directed to providing a device capable of detecting whether mechanical damage of a thermoelectric module occurs.

The present specification is directed to providing a thermoelectric module and a thermoelectric device which are not driven when not worn by a user.

The present specification is directed to providing a thermoelectric module and a thermoelectric device in which operation thereof is stopped when the thermoelectric module is not controlled due to a malfunction.

The problems to be solved by the present specification are not limited to the above-described problems, and other problems which are not mentioned will be clearly understood by those skilled in the art from the present specification and the accompanying drawings.

### Technical Solution

According to one aspect of the present specification, there is provided a thermoelectric device including: a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, a power supply unit configured to output a predetermined current applied to the thermoelectric module to cause the thermoelectric module to perform a thermoelectric operation including an endothermic operation and an exothermic operation so that the thermal stimulus is provided through the first surface, a voltage monitoring unit configured to monitor an output voltage of the thermoelectric module, wherein the output voltage reflects a temperature difference between the first surface and the second surface, a voltage comparison unit configured to compare the output voltage and a reference voltage, and output an application control signal which instructs whether to apply power to the thermoelectric module to stop supplying the power to the thermoelectric module when the temperature difference is greater than or equal to a threshold value, and a power controller configured to adjust whether to apply the power to the thermoelectric module based on the application control signal.

According to another aspect of the present specification, there is provided a thermoelectric device including: a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, and a control module configured to control power supplied to the thermoelectric module, wherein the control module outputs a predetermined current applied to the thermoelectric module to cause the thermoelectric module to perform a thermoelectric operation including an endothermic operation and an exothermic operation so that the thermal stimulus is provided through the first surface, monitors an output voltage of the thermoelectric module, wherein the output voltage reflects a temperature difference between the first surface and the second surface, compares the output voltage and a reference voltage and outputs an application control signal which instructs whether to apply the power to the thermoelectric module to stop supplying the power to the thermoelectric module when the temperature difference is greater than or equal to a threshold value, and adjusts whether to apply the power to the thermoelectric module based on the application control signal.

According to still another aspect of the present specification, there is provided a thermoelectric device including: a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, and a control module configured to control power supplied to the thermoelectric module, wherein the control module outputs a predetermined current applied to the thermoelectric module to cause the thermoelectric module to perform a thermoelectric operation including an endothermic operation and an exothermic operation so that the thermal stimulus is provided through the first surface, monitors an output voltage of the thermoelectric module, and compares the output voltage and a reference voltage to adjust whether to apply the power to the thermoelectric module.

Solutions to the problems of the present specification are not limited to the above-described solutions, and solutions which are not mentioned will be clearly understood by those skilled in the art from the present specification and the accompanying drawings.

### Advantageous Effects

According to an embodiment of the present specification, a malfunction of a thermoelectric module can be prevented by adjusting power applied to the thermoelectric module in consideration of a temperature difference between both surfaces of the thermoelectric module.

According to an embodiment of the present specification, a malfunction of a thermoelectric module can be prevented by adjusting power applied to the thermoelectric module in consideration of a resistance of the thermoelectric module.

According to an embodiment of the present specification, a thermoelectric module can be protected by detecting a temperature of the thermoelectric module without including a separate temperature sensor.

The effects of the invention of the present specification are not limited to the above-described effects, and effects which are not mentioned will be clearly understood by those skilled in the art to which the present invention pertains from the present specification and the accompanying drawings.

### DESCRIPTION OF DRAWINGS

FIG. 1 is a view related to a thermoelectric device according to one embodiment of the present specification.

FIG. 2 is a perspective view related to a thermoelectric module according to one embodiment of the present specification.

FIG. 3 is a cross-sectional view related to the thermoelectric module according to one embodiment of the present specification.

FIG. 4 is a cross-sectional view related to a thermoelectric module including support layers according to one embodiment of the present specification.

FIG. 5 is a view related to an example of the thermoelectric device according to one embodiment of the present specification.

FIG. 6 is a view related to another example of the thermoelectric device according to one embodiment of the present specification.

FIG. 7 is a view related to still another example of the thermoelectric device according to one embodiment of the present specification.

FIG. 8 is a view related to yet another example of the thermoelectric device according to one embodiment of the present specification.

FIGS. 9 and 10 are graphs related to an example of a temperature change of the thermoelectric device according to one embodiment of the present specification.

FIGS. 11 and 12 are graphs related to another example of the temperature change of the thermoelectric device according to one embodiment of the present specification.

FIG. 13 is a graph related to still another example of the temperature change of the thermoelectric device according to one embodiment of the present specification.

FIGS. 14 and 15 are graphs related to yet another example of the temperature change of the thermoelectric device according to one embodiment of the present specification.

FIG. 16 is a view related to a thermoelectric module including a plurality of terminals according to one embodiment of the present specification.

### MODES OF THE INVENTION

Since embodiments described in the present specification are provided to clearly describe the spirit of the present invention to those skilled in the art, the present invention is not limited by the embodiments described in the present specification, and it should be understood that the scope of the present invention includes changes or modifications not departing from the spirit of the present invention.

Widely used general terms are selected as terms used in the present specification as much as possible in consideration of functions in the present invention, but may vary according to an intention of those skilled in the art, a custom, or emergence of new technology. However, when a specific term is defined with an arbitrary meaning and used, the meaning of the term will be separately disclosed. Accordingly, the terms used in this specification should be interpreted based on actual meanings of the terms and the contents throughout the present specification, instead of only names of the terms.

The accompanying drawings in the present specification are provided to easily describe the present invention, and since shapes shown in the drawings may be exaggerated as necessary to help understanding of the present invention, the present invention is not limited by the drawings.

In the description of the present disclosure, when it is determined that detailed descriptions of known configurations or functions related to the present invention may unnecessarily obscure the principle of the present invention, the detailed descriptions thereof will be omitted. Further, numbers (for example, first, second, and the like) used in a description process of the present specification are merely identification symbols for discriminating one component from another.

According to one aspect of the present specification, there is provided a thermoelectric device including: a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, a power supply unit configured to output a predetermined current applied to the thermoelectric module to cause the thermoelectric module to perform a thermoelectric operation including an endothermic operation and an exothermic operation so that the thermal stimulus is provided through the first surface, a voltage monitoring unit configured to monitor an output voltage of the thermoelectric module, wherein the output voltage reflects a temperature difference between the first surface and the second surface, a voltage comparison unit configured to compare the output voltage and a reference voltage, and output an application control signal which instructs whether to apply power to the thermoelectric module to stop supplying the power to the thermoelectric module when the temperature difference is greater than or equal to a threshold value, and a power controller configured to adjust whether to apply the power to the thermoelectric module based on the application control signal.

Here, the thermoelectric module may further include a support layer disposed between the thermoelectric element to support the thermoelectric element while allowing deformation of the thermoelectric module.

Here, the voltage comparison unit may output a first application control signal which instructs not to apply power to the thermoelectric module when the output voltage is greater than or equal to the reference voltage, and the power controller may cut off the power supplied to the thermoelectric module when the first application control signal is input.

Here, the voltage comparison unit may output a second application control signal which instructs to apply power to the thermoelectric module when the output voltage is lower than the reference voltage, and the power controller may allow the power to be supplied to the thermoelectric module when the second application control signal is input.

Here, the power supply unit may output a predetermined current applied to the thermoelectric module based on a resistance of the thermoelectric module to apply a pre-determined current to the thermoelectric module.

Here, the voltage monitoring unit may include a resistor, and may acquire the output voltage based on a voltage applied to the resistor.

Here, the voltage comparison unit may include a comparator.

Here, the power controller may include a transistor.

Here, a polarity determination unit which determines a polarity of the power input to the thermoelectric module so that the thermoelectric module performs the endothermic operation or the exothermic operation may be further included.

Here, the polarity determination unit may include an H-bridge circuit.

Here, the reference voltage may be determined based on at least one of the number of N-type semiconductors and P-type semiconductors, intensity of the thermoelectric operation, a type of the thermoelectric operation, and a fill factor corresponding to an area occupied by the N-type semiconductors and the P-type semiconductors on the first surface.

Here, the thermoelectric operation may include a first thermoelectric operation and a second thermoelectric operation having the same type but having different intensity from the first thermoelectric operation, and the reference voltage may include a first reference voltage corresponding to the first thermoelectric operation and a second reference voltage corresponding to the second thermoelectric operation and different from the first reference voltage.

Here, when the thermoelectric module performs the exothermic operation, the reference voltage may be the first reference voltage, and when the thermoelectric module performs the endothermic operation, the reference voltage may be the second reference voltage different from the first reference voltage.

According to another aspect of the present specification, there is provided a thermoelectric device including: a thermoelectric module having a first surface providing a thermal stimulus to a user and a second surface opposite the first surface, and including an N-type semiconductor and a P-type semiconductor disposed between the first surface and the second surface and electrodes configured to electrically connect the N-type semiconductor and the P-type semiconductor, and a control module configured to control power supplied to the thermoelectric module, wherein the control module outputs a predetermined current applied to the thermoelectric module to cause the thermoelectric module to perform a thermoelectric operation including an endothermic operation and an exothermic operation so that the thermal stimulus is provided through the first surface, monitors an output voltage of the thermoelectric module, wherein the output voltage reflects a temperature difference between the first surface and the second surface, compares the output voltage and a reference voltage and outputs an application control signal which instructs whether to apply the power to the thermoelectric module to stop supplying the power to the thermoelectric module when the temperature difference is greater than or equal to a threshold value, and adjusts whether to apply the power to the thermoelectric module based on the application control signal.

According to still another aspect of the present specification, there is provided a thermoelectric device including: a thermoelectric module having a first surface providing a thermal stimulus to a user and a second surface opposite the first surface, and including an N-type semiconductor and a P-type semiconductor disposed between the first surface and the second surface and electrodes configured to electrically connect the N-type semiconductor and the P-type semiconductor, and a control module configured to control power supplied to the thermoelectric module, wherein the control module outputs a predetermined current applied to the thermoelectric module to cause the thermoelectric module to perform a thermoelectric operation including an endothermic operation and an exothermic operation so that the thermal stimulus is provided through the first surface, monitors an output voltage of the thermoelectric module, and compares the output voltage and a reference voltage to adjust whether to apply the power to the thermoelectric module.

Hereinafter, a thermoelectric module protection circuit and a thermoelectric device including the same according to the embodiment of the present specification will be described.

The thermoelectric device according to the embodiment of the present specification is a device providing a thermal stimulus to a user. Specifically, the thermoelectric device may provide the thermal stimulus to the user by performing an exothermic operation or an endothermic operation to apply heat to the user or absorb heat from the user.

The thermal stimulus involves stimulating the user's thermal sense organs mainly distributed in the user's body to cause the user to feel a thermal sensation, and in the present specification, it should be understood that the thermal stimulus encompasses all stimulation of the user's thermal sense organs.

A feeling of warmth and a feeling of coldness may be representative examples of the thermal stimulus. The feeling of warmth means applying warm heat to a hot spot distributed on the skin so that the user feels the feeling of warmth, and the feeling of coldness means applying cold heat to a cold spot distributed on the skin so that the user feels the feeling of coldness.

Here, since the heat is a physical quantity expressed in a positive scalar form, the expression “applying cold heat” may not be a strict expression from a physical point of view, but in the present specification, for convenience of description, a phenomenon in which heat is applied will be expressed as a case in which warm heat is applied, and a reverse phenomenon, that is, a phenomenon in which heat is absorbed, will be expressed as a case in which cold heat is applied.

Further, in the present specification, the thermal stimulus may further include a thermal grill illusion (TGI) in addition to the feeling of warmth and the feeling of coldness. The user perceives the warm heat and the cold heat as a sensation instead of individually perceiving the feeling of warmth and the feeling of coldness when the feeling of warmth and the feeling of coldness are simultaneously given, and this sensation is referred to as the thermal grill illusion. That is, the thermal grill illusion refers to a thermal stimulus in which the warm heat and the cold heat are complexly applied, and may be mainly provided by simultaneously outputting the feeling of warmth and the feeling of coldness. Further, the thermal grill illusion may be referred to as a thermal sensation in an aspect of providing a sensation close to the sensation.

The type of thermal stimulus provided by the thermoelectric module may correspond to the polarity of power applied to the thermoelectric module. According to one embodiment, the type of thermal stimulus provided by the thermoelectric module may be determined based on the polarity of power applied to the thermoelectric module. For example, when power of a first polarity (for example, a (+) polarity) is applied to the thermoelectric module, the thermoelectric module outputs one of warm heat and cold heat, and when power of a second polarity (for example, a (−) polarity) is applied, the thermoelectric module may output the other one of the warm heat and the cold heat.

The intensity of the thermal stimulus provided by the thermoelectric module may be various. In the present specification, a case in which the intensity of the thermal stimulus is high means that a strong thermal stimulus is provided to the user.

Even the same type of thermal stimuli may have different intensity. For example, a first thermal stimulus having a first intensity may provide a stronger thermal stimulus compared to a second thermal stimulus having a second intensity smaller than the first intensity to the user.

The intensity of the thermal stimulus provided by the thermoelectric module may correspond to a magnitude of power applied to the thermoelectric module. According to one embodiment, the intensity of the thermal stimulus provided by the thermoelectric module may be determined based on the magnitude of power applied to the thermoelectric module. For example, the intensity of the thermal stimulus provided by the thermoelectric module may be larger as the magnitude of power applied to the thermoelectric module is larger. Here, the magnitude of power may be at least one of a magnitude of a current and a magnitude of a voltage.

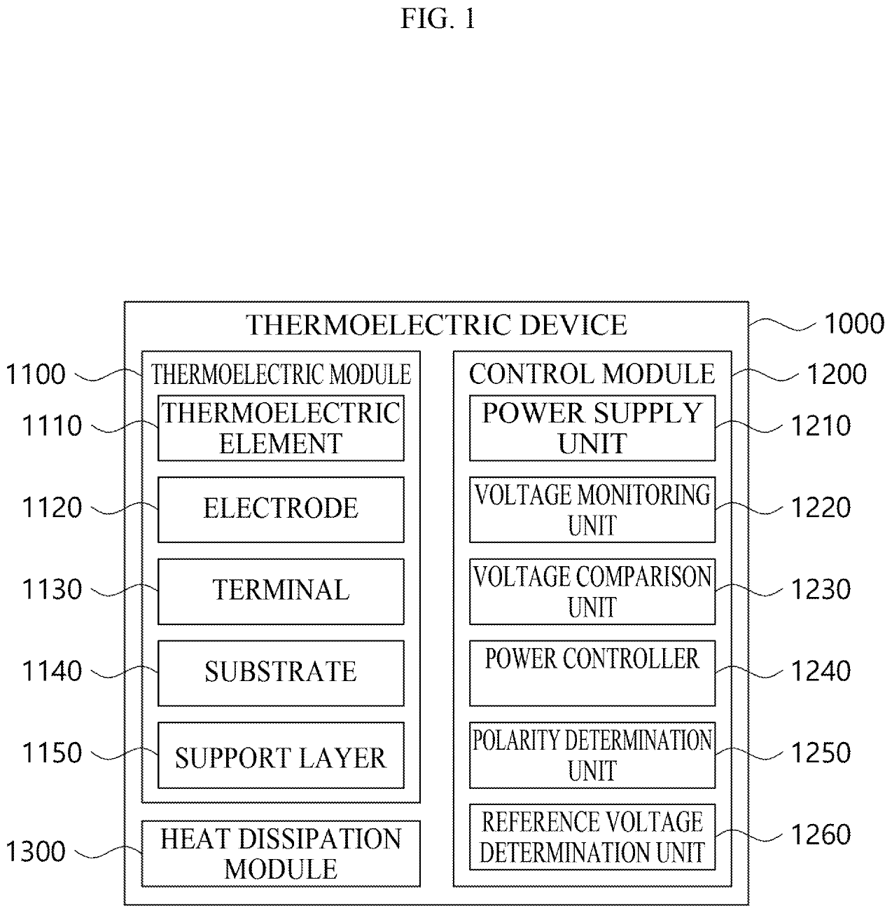

FIG. 1 is a view related to a thermoelectric device according to one embodiment of the present specification. Referring to FIG. 1, a thermoelectric device 1000 according to one embodiment of the present specification may include a thermoelectric module 1100, a control module 1200, and a heat dissipation module 1300. In the thermoelectric device 1000, the control module 1200 may provide a thermal stimulus to a user by controlling the thermoelectric module 1100 to selectively or simultaneously perform an exothermic operation or an endothermic operation, and waste heat due to a thermoelectric operation of the thermoelectric module 1100 may be discharged to the outside of the thermoelectric device 1000 through the heat dissipation module 1300.

The thermoelectric device 1000 according to one embodiment of the present specification may include the thermoelectric module 1100.

The thermoelectric module may refer to a module which performs a power generation operation using a temperature difference using a thermoelectric effect such as the Seebeck effect, the Peltier effect, or the like or performs a thermoelectric operation of a heating operation, a cooling operation, or the like using electric energy. For example, the thermoelectric module may provide a thermal stimulus including a feeling of warmth, a feeling of coldness, and a thermal grill illusion to the user through the thermoelectric operation.

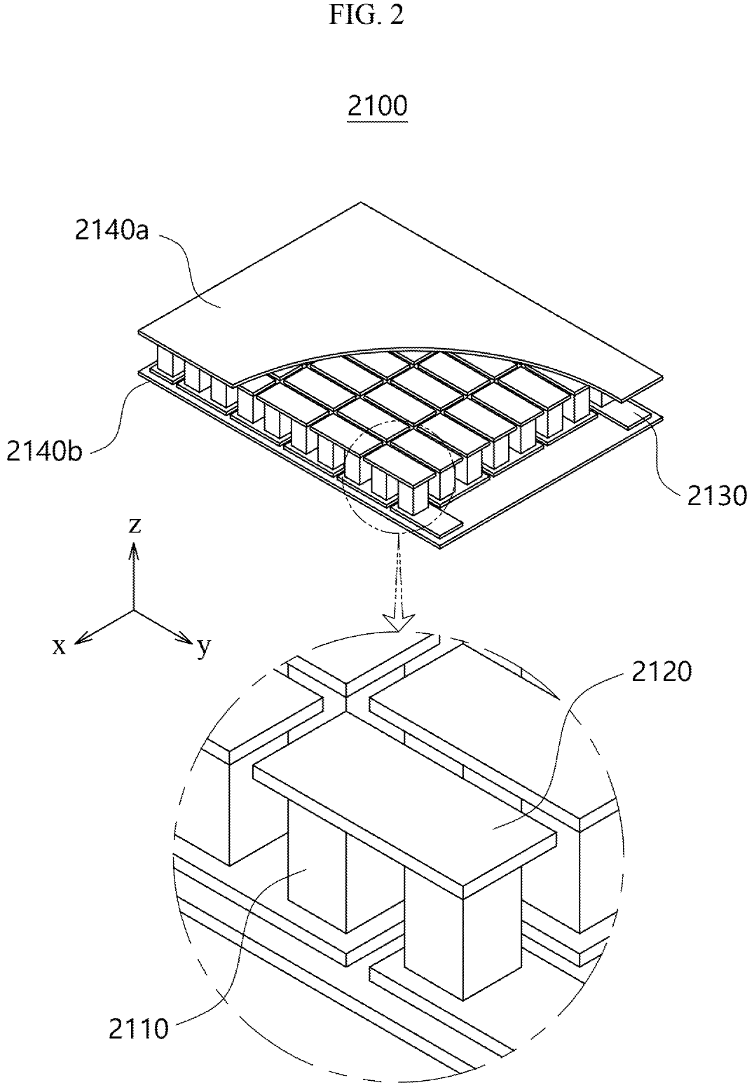

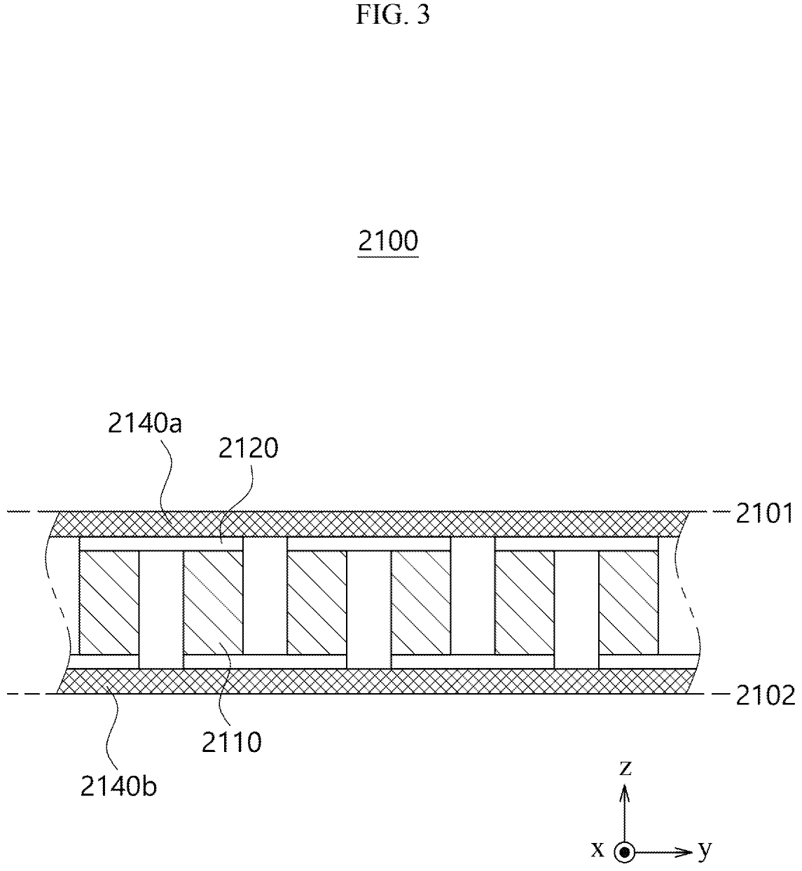

FIG. 2 is a perspective view related to the thermoelectric module according to one embodiment of the present specification, and FIG. 3 is a cross-sectional view related to the thermoelectric module according to one embodiment of the present specification.

The thermoelectric module may be provided in a plate shape. Further, the thermoelectric module may have flexibility (hereinafter referred to as “a flexible thermoelectric module”). The flexible thermoelectric module is basically provided in the plate shape, but has flexibility in which curving is possible, and thus may be deformed into various shapes including a curved shape. Further, the flexible thermoelectric module which may be deformed between a flat shape and a curved shape may be provided. For example, a flexible thermoelectric module 2100 of a flat shape as shown in FIG. 2 may be deformed into a curved shape by applying a force, and when the applied force is removed, the flexible thermoelectric module 2100 in the curved shape may be recovered to the flat shape.

The thermoelectric module may have both surfaces facing each other. For example, referring to FIG. 3, the thermoelectric module 2100 may include a first surface 2101 and a second surface 2102 opposite the first surface 2101. At least some among thermoelectric elements 2110, electrodes 2120, terminals, substrates 2140a and 2140b, and support layers may be disposed between the first surface 2101 and the second surface 2102. Although the first surface 2101 and the second surface 2102 are shown as flat surfaces in FIGS. 2 and 3, when the thermoelectric module is provided as a curved surface, the first surface and the second surface may also be curved surfaces.

The thermoelectric module may provide the thermal stimulus to the user through one surface and discharge waste heat generated during a thermoelectric operation through the other surface. Here, the one surface and the other surface may be opposite each other. For example, referring to FIG. 3, the thermoelectric module 2100 may provide the thermal stimulus to the user through one of the first surface 2101 and the second surface 2102, and discharge the waste heat through the other one.

According to one embodiment, the thermoelectric module 1100 may include thermoelectric elements 1110.

The thermoelectric elements may be elements which cause the thermoelectric effect such as the Seebeck effect, the Peltier effect, or the like. Basically, the thermoelectric elements may include a first thermoelectric element and a second thermoelectric element made of different materials constituting a thermoelectric pair (thermoelectric couple) which causes the thermoelectric effect. The first thermoelectric element and the second thermoelectric element are electrically connected to each other to form a thermoelectric pair. The thermoelectric pair may generate a temperature difference when electrical energy is applied, and on the other hand, may produce electrical energy when a temperature difference is applied. A pair of bismuth telluride (Bi—Te) and antimony telluride (Sb—Te) is a representative example of the thermoelectric element. Further, recently, a pair of an N-type semiconductor and a P-type semiconductor has been mainly used as a thermoelectric element.

According to one embodiment, the thermoelectric module 1100 may include electrodes 1120.

The electrodes electrically connect the thermoelectric elements. The thermoelectric elements may generate the thermoelectric effect only when at least the first thermoelectric element and the second thermoelectric element made of different materials are electrically connected to each other to form the thermoelectric pair. Accordingly, the electrodes may form a thermoelectric pair by connecting the first thermoelectric element and the second thermoelectric element adjacent to each other. For example, referring to FIGS. 2 and 3, the electrodes 2120 may connect the thermoelectric elements 2110 adjacent to each other. Of course, the electrodes may electrically connect the thermoelectric elements of the same material, such as connecting the first thermoelectric element and the first thermoelectric element, connecting the second thermoelectric element and the second thermoelectric element, or the like.

Further, the electrodes may connect a plurality of thermoelectric elements in series. The thermoelectric elements connected in series by the electrodes may form a thermoelectric group which simultaneously performs the same thermoelectric operation.

The electrodes may be provided with a metal material such as copper, silver, or the like, but the present invention is not limited thereto.

FIGS. 2 and 3 illustrate that the electrodes 2120 are disposed in a form that covers both upper surfaces and lower surfaces of the thermoelectric elements 2110, but a size relationship between the electrodes 2120 and the thermoelectric elements 2110 is not limited thereto, and the electrodes 2120 may be disposed in a form that covers only portions of the upper surfaces or the lower surfaces of the thermoelectric elements 2110.

According to one embodiment, the thermoelectric module 1100 may include terminals 1130.

The terminals are terminals that connect the thermoelectric module to the outside. Referring to FIG. 2, the thermoelectric module 2100 may receive power from the outside through the terminals 2130. Alternatively, the thermoelectric module may be connected to the control module through the terminals.

When the thermoelectric module is used as a heat outputting module, the terminals may transfer power for performing a heating/cooling operation using the Peltier effect to the thermoelectric module from the outside. Alternatively, when the thermoelectric module is used as a thermoelectric generating module, the terminal may transfer power generated by the thermoelectric module using the Seebeck effect to the outside.

According to one embodiment, the thermoelectric module 1100 may include substrates 1140.

A pair of substrates may be disposed to be spaced apart from each other and opposite each other. Referring to FIGS. 2 and 3, the thermoelectric module 2100 may include a pair of substrates 2140a and 2140b opposite each other. The substrates may support the thermoelectric elements or the electrodes disposed therebetween. Further, the substrates may perform a function of protecting the thermoelectric elements or the electrodes therein from the outside.

The substrates may be provided with a material which easily conducts heat and has flexibility. For example, the substrates may be thin polyimide (PI) films. The polyimide films may have excellent flexibility, and although the polyimide films do not have high thermal conductivity, the polyimide films may be manufactured in a thin thickness, which is advantageous for conducting heat.

The substrate may be disposed on only one surface of the thermoelectric module. The thermoelectric module having the substrate on only one surface has an advantage of having improved flexibility compared to the thermoelectric module having the substrates on both surfaces because the substrate has some resistance to curving or the like even when provided with a flexible material such as a PI film.

In the thermoelectric module having the substrate on only one surface, a surface not having the substrate thereon may have greater flexibility than the opposite surface. When the surface not having the substrate thereon is used as a convex portion while using the thermoelectric module in a curved shape, these advantages may be fully taken.

According to one embodiment, the thermoelectric module 1100 may include support layers 1150.

The support layers may be located between the pair of substrates. The support layers may support the thermoelectric elements and the electrodes. Accordingly, the thermoelectric elements and the electrodes may be supported together with the substrates by the support layers.

The support layers may be provided with a flexible material so that the thermoelectric module may maintain flexibility. For example, the support layers may be foaming layers having internal pores like a sponge. Here, the foaming layers may be formed by filling a foaming agent between a pair of substrates. An organic foaming agent, an inorganic foaming agent, a physical foaming agent, polyurethane, silicone foam, and the like may be used as the foaming agent.

When the support layers are included in the thermoelectric module, since the thermoelectric elements and the electrodes may be supported by the support layers, the substrates may not necessarily be required. For example, any one of the pair of substrates 2140a and 2140b shown in FIGS. 2 and 3 may be removed. Alternatively, both of the pair of substrates 2140a and 2140b may be removed. When the substrates are removed, the flexibility of the thermoelectric module may be improved. Alternatively, when the substrates are removed, a thermal capacity of the thermoelectric module may decrease.

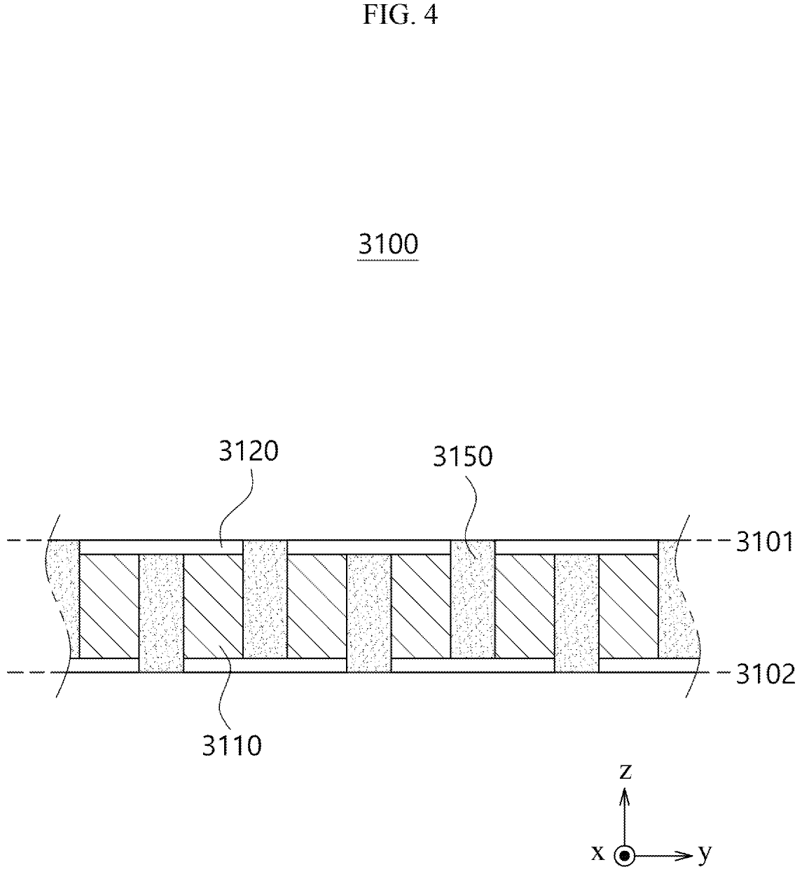

FIG. 4 is a cross-sectional view related to a thermoelectric module including support layers according to one embodiment of the present specification. Comparing FIGS. 3 and 4, a thermoelectric module 3100 may include support layers 3150 but not substrates. The thermoelectric module 3100 may include a first surface 3101 and a second surface 3102 opposite the first surface 3101. Here, the thermoelectric module 3100 may provide the thermal stimulus to the user through one of the first surface 3101 and the second surface 3102, and discharge the waste heat through the other one.

The above-described thermoelectric module is only an example, and the thermoelectric module may be provided without some components or with other additional components.

The thermoelectric device 1000 according to one embodiment of the present specification may include the control module 1200.

The control module may control the overall operation of the thermoelectric device. For example, the control module may be connected to a terminal of the thermoelectric module to apply power to the thermoelectric element to control the thermoelectric module so that the thermoelectric module may perform an exothermic operation or an endothermic operation.

To this end, the control module may control the operation of the thermoelectric module by performing calculation and processing of various pieces of information and outputting an electrical signal to the thermoelectric module according to a processing result. Accordingly, the control module may be implemented as a computer or similar device according to hardware, software, or a combination thereof. In the hardware, the control module may be provided in a form of an electronic circuit which performs a control function by processing electrical signals, and in the software, the control module may be provided in a form of a program or code which drives a hardware circuit. In the following description, unless otherwise mentioned, it may be interpreted that the operation of the thermoelectric device is performed by the control of the control module.

The control module may be configured to apply power to the thermoelectric module. For example, the control module may apply power to the thermoelectric module based on the thermal stimulus provided by the thermoelectric module.

According to one embodiment, the control module may include the power supply unit for applying power to the thermoelectric module. For example, the power supply unit may apply power to the thermoelectric module based on the thermal stimulus provided by the thermoelectric module. Alternatively, the power supply unit may apply power to the thermoelectric module based on the resistance of the thermoelectric module. In this case, the power supply unit may apply a predetermined current to the thermoelectric module.

According to one embodiment, the control module may include a polarity determination unit which adjusts or determines a polarity of power input to the thermoelectric module. The polarity determination unit may include an H-bridge circuit, but is not limited thereto.

As described above, the polarity of the power applied to the thermoelectric module may correspond to the type of thermal stimulus provided by the thermoelectric module. Further, the magnitude of the power applied to the thermoelectric module may correspond to the intensity of the thermal stimulus provided by the thermoelectric module.

The control module may be configured to monitor an output voltage of the thermoelectric module. For example, when a predetermined current is applied to the thermoelectric module, the control module may monitor the output voltage of the thermoelectric module. Here, the output voltage may correspond to a voltage between both ends of the thermoelectric module. For example, the output voltage may be a voltage between both terminals of the thermoelectric module.

According to one embodiment, the control module may include a power monitoring unit for monitoring the output voltage of the thermoelectric module. For example, when the predetermined current is applied to the thermoelectric module, the power monitoring unit may monitor the output voltage of the thermoelectric module. In this case, the power monitoring unit may be referred to as a voltage monitoring unit. Here, monitoring the output voltage may include acquiring or calculating the magnitude of the output voltage.

According to one embodiment, the power monitoring unit may include a resistor. For example, the power monitoring unit may acquire or calculate the output voltage of the thermoelectric module based on a voltage applied to the resistor.

Meanwhile, when a predetermined current is applied to the thermoelectric module, the output voltage of the thermoelectric module may reflect the resistance of the thermoelectric module. For example, since a higher voltage is required to apply a current of the same magnitude as the resistance of the thermoelectric module increases, the output voltage may also increase. Accordingly, when a problem such as cracking inside the thermoelectric module, such as a bonding fault between the thermoelectric elements and the electrodes, or the like occurs, the resistance of the thermoelectric module may increase and the output voltage of the thermoelectric module may also increase.

Alternatively, when the predetermined current is applied to the thermoelectric module, the output voltage of the thermoelectric module may reflect a temperature difference between both surfaces of the thermoelectric module. For example, referring to FIGS. 2 to 4, the output voltage of the thermoelectric module may increase due to a thermoelectromotive force as the temperature difference between one surface providing the thermal stimulus and the other surface opposite the one surface increases. Here, the output voltage of the thermoelectric module may increase due to an increase in resistance of the thermoelectric module due to the thermoelectromotive force. That is, the temperature difference between both surfaces of the thermoelectric module may be monitored by monitoring the output voltage, specifically, the magnitude of the output voltage.

Accordingly, the thermoelectric module may be protected by monitoring the output voltage of the thermoelectric module. Alternatively, a malfunction of the thermoelectric module may be detected by monitoring the output voltage of the thermoelectric module. For example, whether the thermoelectric module comes into contact with the user or whether the user is wearing the thermoelectric device may be determined by monitoring the output voltage of the thermoelectric module. As another example, whether cracking occurs in the thermoelectric module may be determined by monitoring the output voltage of the thermoelectric module. In the present specification, a case in which the thermoelectric module malfunctions means that the thermoelectric module operates in an undesired situation or is not controlled as intended such as when the thermoelectric module operates in a situation in which the user is not in contact with the thermoelectric module, the user is not wearing the thermoelectric device, or the like or when the thermoelectric module is not controlled in a situation in which the thermoelectric module is at maximum output.

It may be advantageous to detect the malfunction as the thermal capacity of the thermoelectric module is smaller. For example, when the malfunction occurs and the thermoelectric module operates in the situation in which the thermoelectric module is not in contact with the user or the user is not wearing the thermoelectric device, since a larger temperature difference occurs in a thermoelectric module having a small thermal capacity compared to a thermoelectric module having a large thermal capacity, the output voltage will also significantly increase. On the other hand, the thermoelectric module having a large thermal capacity may have a relatively small temperature difference, and thus it may be difficult to detect a malfunction even when the output voltage is monitored. In a severe case, since almost no temperature difference occurs, the malfunction may not be detected even when the output voltage is monitored. As described above, when the thermoelectric module includes the substrates, the thermal capacity increases compared to a case in which the thermoelectric module does not include the substrates. Accordingly, the case in which the thermoelectric module does not include the substrates may be advantageous for detecting a malfunction by monitoring the output voltage compared to the case in which the thermoelectric module includes the substrates.

The control module may be configured to adjust whether to apply power to the thermoelectric module. For example, the control module may determine whether to apply power to the thermoelectric module based on the output voltage of the thermoelectric module. For example, the control module may apply power to the thermoelectric module when the output voltage is within a predetermined range, and may not apply power to the thermoelectric module when the output voltage is out of the range.

According to one embodiment, the control module may determine whether to apply power to the thermoelectric module based on the output voltage and a reference voltage of the thermoelectric module. For example, the control module may not apply power to the thermoelectric module when the output voltage is greater than or equal to the reference voltage. As another example, the control module may apply power to the thermoelectric module when the output voltage is lower than the reference voltage.

The reference voltage may be a predetermined fixed value. Alternatively, the reference voltage may be a variable value that changes according to the surrounding environment such as temperature, humidity, or the like.

The reference voltage may be determined in consideration of various conditions. For example, the reference voltage may be determined based on at least one among characteristics of power applied to the thermoelectric module, the number of thermoelectric elements in the thermoelectric module, and a fill factor of the thermoelectric module. Here, the fill factor may be a ratio of an area occupied by the thermoelectric elements on one surface of the thermoelectric module in contact with or adjacent to the user.

According to one embodiment, the reference voltage may be determined based on the characteristic of the power applied to the thermoelectric module.

For example, the reference voltage may be determined based on the magnitude of power applied to the thermoelectric module. For example, a first reference voltage corresponding to a case in which the magnitude of power (for example, the magnitude of current) applied to the thermoelectric module is a first value may be different from a second reference voltage corresponding to a second value greater than the first value. Here, the first reference voltage may be greater than the second reference voltage, but the present invention is not limited thereto. Further, since the magnitude of power applied to the thermoelectric module is related to the intensity of the thermal stimulus, it can be seen that the reference voltage may be determined based on the intensity of the thermal stimulus. Of course, the reference voltage may be determined regardless of the magnitude of power applied to the thermoelectric module or the intensity of the thermal stimulus.

As another example, the reference voltage may be determined based on the polarity of power applied to the thermoelectric module. For example, the first reference voltage corresponding to the case in which the polarity of power applied to the thermoelectric module is the first polarity may be different from the second reference voltage corresponding to the case in which the polarity of power applied to the thermoelectric module is the second polarity. Further, since the polarity of power applied to the thermoelectric module is related to the type of thermal stimulus, it can be seen that the reference voltage may be determined based on the type of thermal stimulus. As a non-restrictive example, the reference voltage corresponding to a case in which the thermoelectric module provides a feeling of warmth may be greater than the reference voltage corresponding to a case in which the thermoelectric module provides a feeling of coldness. Of course, the reference voltage may be determined regardless of the polarity of power applied to the thermoelectric module or the type of thermal stimulus.

According to one embodiment, the reference voltage may be determined based on the number of thermoelectric elements of the thermoelectric module. For example, the first reference voltage corresponding to a case in which the number of thermoelectric elements is one may be different from the second reference voltage corresponding to a case in which the number of thermoelectric elements is not one but two. Of course, the reference voltage may be determined regardless of the number of thermoelectric elements.

According to one embodiment, the reference voltage may be determined based on the fill factor of the thermoelectric module. For example, the first reference voltage corresponding to a case in which the fill factor of the thermoelectric module is a first value may be different from the second reference voltage corresponding to a case in which the fill factor is a second value different from the first value. Of course, the reference voltage may be determined regardless of the fill factor.

The reference voltage may be determined by the control module. In this case, the control module may determine the reference voltage based on the above-described condition. Alternatively, the control module may include a reference voltage determination unit which determines the reference voltage. In this case, the reference voltage determination unit may determine the reference voltage based on the above-described condition.

According to one embodiment, the control module may adjust whether to apply power to the thermoelectric module based on an application control signal which contains instructions regarding whether to apply power to the thermoelectric module. Here, the application control signal may be determined based on the at least one of the output voltage and the reference voltage of the thermoelectric module. For example, the application control signal may be a signal which instructs not to apply power to the thermoelectric module when the output voltage is greater than or equal to the reference voltage. As another example, the application control signal may be a signal which instructs to apply power to the thermoelectric module when the output voltage is lower than the reference voltage.

According to one embodiment, the control module may include a voltage comparison unit which outputs the application control signal based on the output voltage and the reference voltage. For example, the voltage comparison unit may compare the output voltage and the reference voltage to output the application control signal. For example, the voltage comparison unit may output a first application control signal which instructs not to apply power to the thermoelectric module when the output voltage is greater than or equal to the reference voltage. As another example, when the output voltage is lower than the reference voltage, the voltage comparison unit may output a second application control signal which instructs to apply power to the thermoelectric module. The voltage comparison unit may include at least one among a comparator, a logic circuit, and a microcontroller unit (MCU), but the present invention is not limited thereto.

According to one embodiment, the control module may include a power controller which adjust whether to apply power to the thermoelectric module based on the application control signal. For example, when the signal which instructs not to apply power to the thermoelectric module is input, the power controller may cut off the power supplied to the thermoelectric module. As another example, when the signal which instructs to apply power to the thermoelectric module is input, the power controller may allow the power to be applied to the thermoelectric module. The power controller may include a transistor, but the present invention is not limited thereto.

The thermoelectric device 1000 according to one embodiment of the present specification may include the heat dissipation module 1300.

The heat dissipation module may discharge heat absorbed from the thermoelectric module to the outside. For example, waste heat generated as the thermoelectric module operates may be transferred to the heat dissipation module, and the heat dissipation module may discharge the received waste heat to the outside.

The heat dissipation module may be implemented with a material having high thermal conductivity. For example, the heat dissipation module may be implemented using a metal material and/or an alloy material such as aluminum or magnesium. As another example, the heat dissipation module may be implemented using a thermally conductive polymer. In addition, the heat dissipation module may be implemented with various materials such as a ceramic, a carbon composite material, a polymer/metal composite material, a polymer/ceramic composite material, and the like.

In the heat dissipation module, one region is disposed to correspond to a high temperature region and another region is disposed to correspond to a low temperature region. The heat dissipation module may be formed in a structure capable of increasing an area in contact with the low temperature region. For example, in the heat dissipation module, the one region may be provided in a plate shape and the other region may be provided in a fin shape. Alternatively, the other region may be formed to have a protrusion and a recessed portion. Of course, both the one region and the other region of the heat dissipation module may each be provided in a plate shape.

The thermoelectric device according to the above-described embodiment of the present specification may be variously implemented. Hereinafter, some examples of thermoelectric devices according to the embodiment of the present specification will be described.

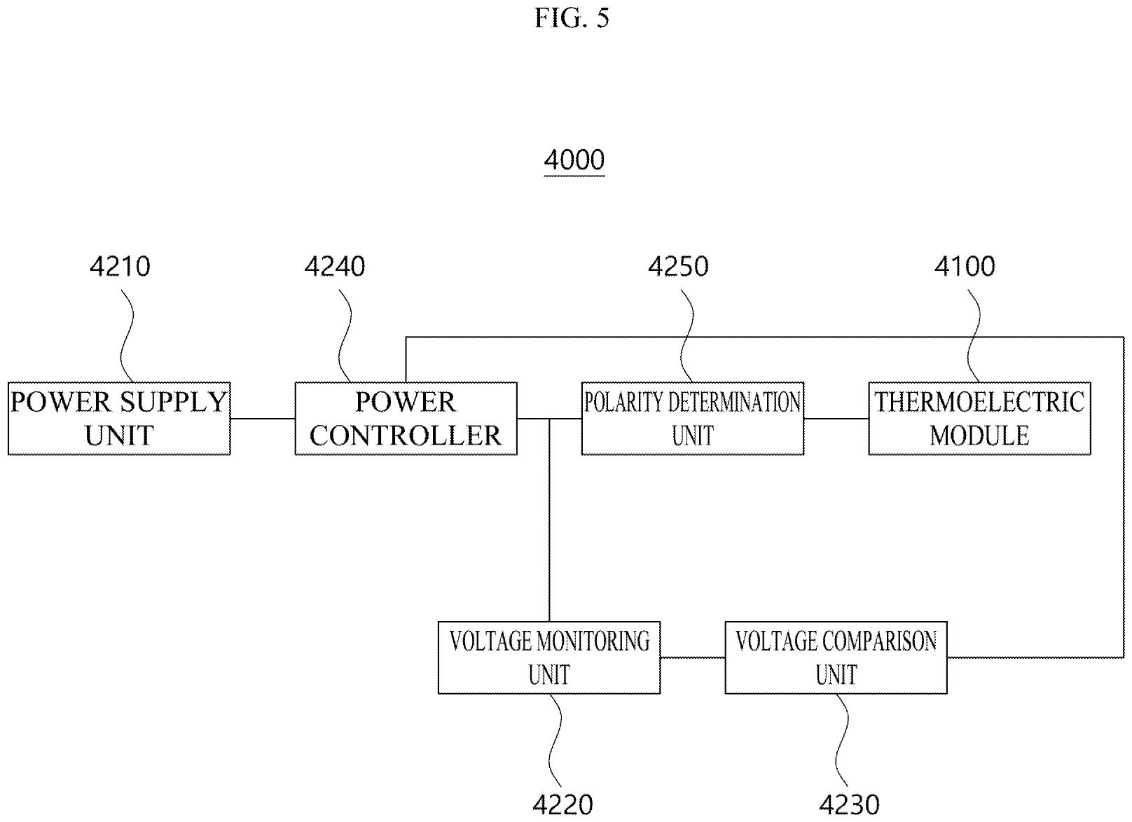

FIG. 5 is a view related to an example of a thermoelectric device according to one embodiment of the present specification. Referring to FIG. 5, a thermoelectric device 4000 according to one embodiment of the present specification may include a thermoelectric module 4100, a power supply unit 4210, a voltage monitoring unit 4220, a voltage comparison unit 4230, a power controller 4240, and a polarity determination unit 4250. The thermoelectric module 4100 may provide a thermal stimulus to a user. The thermoelectric module 4100 may be electrically connected to the polarity determination unit 4250. The power supply unit 4210 may provide power to be supplied to the thermoelectric module 4100. The power supply unit 4210 may be electrically connected to the power controller 4240. The power controller 4240 may determine whether to apply the power provided by the power supply unit 4210 to the thermoelectric module 4100 based on an application control signal output from the voltage comparison unit 4230. The power controller 4240 may be electrically connected to the power supply unit 4210, the voltage monitoring unit 4220, the voltage comparison unit 4230, and the polarity determination unit 4250. The polarity determination unit 4250 may determine a polarity of the power supplied to the thermoelectric module 4100. The polarity determination unit 4250 may be electrically connected to the thermoelectric module 4100, the voltage monitoring unit 4220, and the power controller 4240. The voltage monitoring unit 4220 may monitor an output voltage of the thermoelectric module 4100. The voltage monitoring unit 4220 may output the output voltage of the thermoelectric module 4100. The voltage monitoring unit 4220 may be electrically connected to the power controller 4240, the polarity determination unit 4250, and the voltage comparison unit 4230. FIG. 5 illustrates that the voltage monitoring unit 4220 is connected between the power controller 4240 and the polarity determination unit 4250 to monitor the output voltage of the thermoelectric module 4100, but the present invention is not limited thereto, and the voltage monitoring unit 4220 may be connected differently from the case shown in the drawing when monitoring the output voltage of the thermoelectric module 4100 is possible such as being connected between the polarity determination unit 4250 and the thermoelectric module 4100 to monitor the output voltage or the like. The voltage comparison unit 4230 may compare the output voltage monitored by the voltage monitoring unit 4220 with a reference voltage. The voltage comparison unit 4230 may output the application control signal based on the output voltage and the reference voltage. The voltage comparison unit 4230 may transmit the application control signal to the power controller 4240. The voltage comparison unit 4230 may be electrically connected to the voltage monitoring unit 4220 and the power controller 4240.

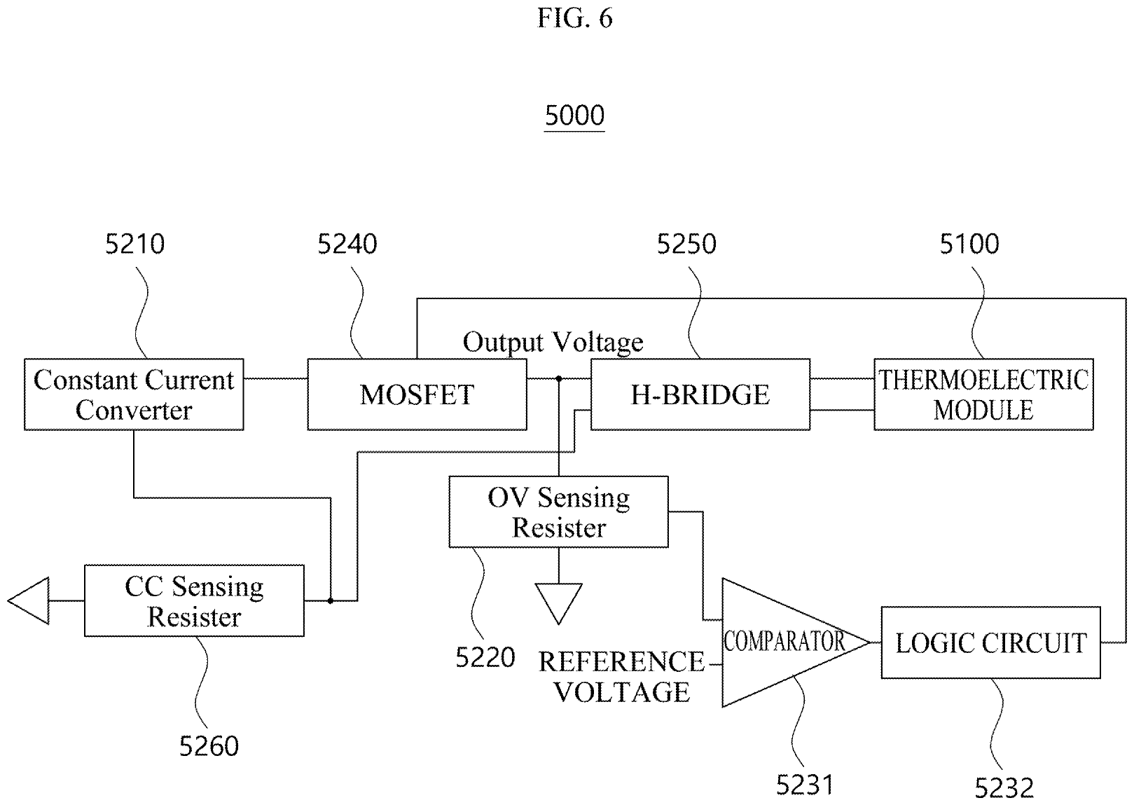

FIG. 6 is a view related to another example of the thermoelectric device according to one embodiment of the present specification. Referring to FIG. 6, a thermoelectric device 5000 according to one embodiment of the present specification may include a thermoelectric module 5100, a constant current converter 5210, an output voltage (OV) sensing resistor 5220, a comparator 5231, a logic circuit 5232, a metal-oxide semiconductor field-effect-transistor (MOSFET) 5240, an H-bridge 5250, and a constant current (CC) sensing resistor 5260. The thermoelectric module 5100 may provide a thermal stimulus to a user. The thermoelectric module 5100 may be electrically connected to the H-bridge 5250. The constant current converter 5210 may provide a predetermined current to be supplied to the thermoelectric module 5100. The constant current converter 5210 may be electrically connected to the MOSFET 5240 and the constant current sensing resistor 5260. The MOSFET 5240 may determine whether the current provided by the constant current converter 5210 is applied to the thermoelectric module 5100 based on an interrupt output from the logic circuit 5232. The MOSFET 5240 may be electrically connected to the constant current converter 5210, the output voltage sensing resistor 5220, the logic circuit 5232, and the H-bridge 5250. The H-bridge 5250 may determine a polarity of the current supplied to the thermoelectric module 5100. The H-bridge 5250 may be electrically connected to the thermoelectric module 5100, the output voltage sensing resistor 5220, the MOSFET 5240, and the constant current sensing resistor 5260. The output voltage sensing resistor 5220 may sense an output voltage of the thermoelectric module 5100. The output voltage sensing resistor 5220 may output the output voltage of the thermoelectric module 5100. The output voltage sensing resistor 5220 may be electrically connected to the MOSFET 5240, the H-bridge 5250, and the comparator 5231. The comparator 5231 may compare the output voltage sensed by the output voltage sensing resistor 5220 with the reference voltage. The comparator 5231 may be electrically connected to the output voltage sensing resistor 5220 and the logic circuit 5232. The logic circuit 5232 may output the interrupt based on an output of the comparator 5231. The logic circuit 5232 may transfer the interrupt to the MOSFET 5240. The logic circuit 5232 may be electrically connected to the comparator 5231 and the MOSFET 5240. The constant current sensing resistor 5260 may detect a resistance of the thermoelectric module 5100 for outputting the predetermined current to output the output voltage. The constant current sensing resistor 5260 may be electrically connected to the constant current converter 5210 and the H-bridge 5250.

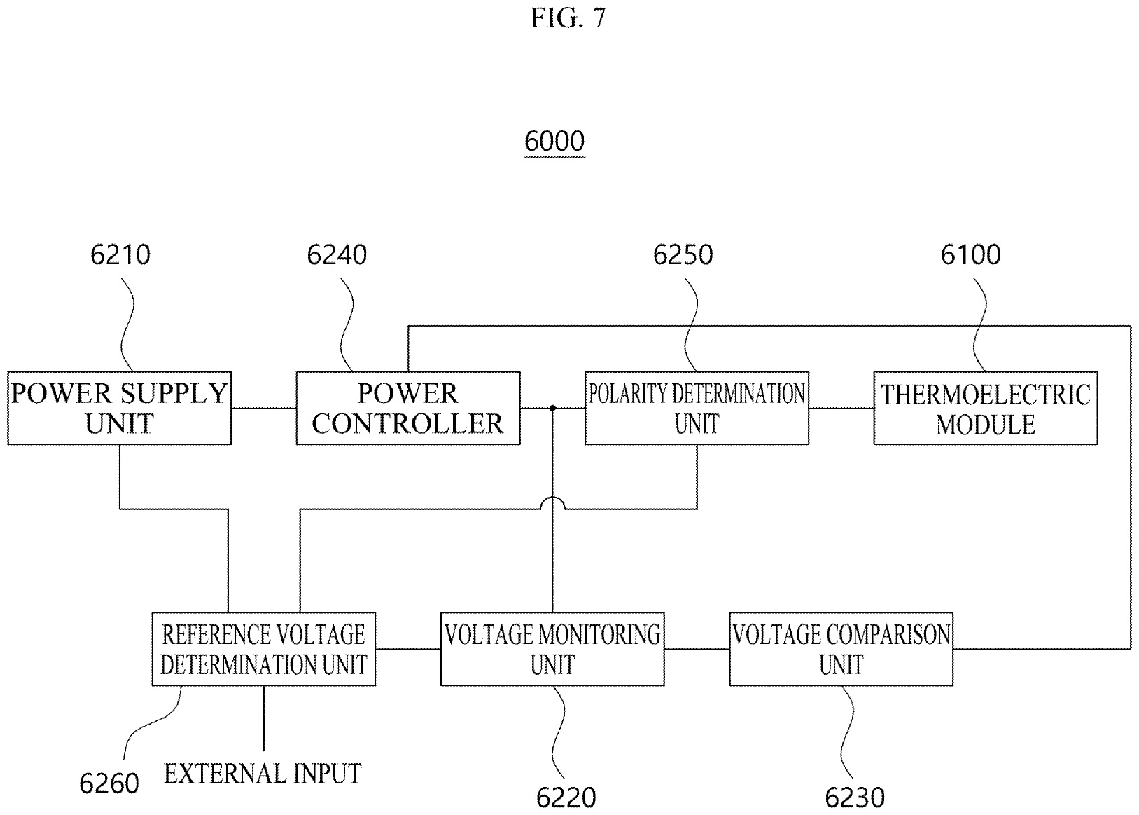

FIG. 7 is a view related to still another example of the thermoelectric device according to one embodiment of the present specification. Referring to FIG. 7, a thermoelectric device 6000 according to one embodiment of the present specification may include a thermoelectric module 6100, a power supply unit 6210, a voltage monitoring unit 6220, a voltage comparison unit 6230, a power controller 6240, a polarity determination unit 6250, and a reference voltage determination unit 6260. In comparison with FIG. 5, FIG. 7 relates to the thermoelectric device 6000 further including the reference voltage determination unit 6260, and in order to avoid repeated description, the added content will be mainly described here. The reference voltage determination unit 6260 may be electrically connected to the power supply unit 6210, the polarity determination unit 6250, and the voltage monitoring unit 6220. The reference voltage determination unit 6260 may output a reference voltage to the voltage monitoring unit 6220. The reference voltage determination unit 6260 may output the reference voltage based on at least one of a magnitude and a polarity of the power. For example, the reference voltage determination unit 6260 may acquire the magnitude of the power applied to the thermoelectric module 6100 from the power supply unit 6210. As another example, the reference voltage determination unit 6260 may acquire the polarity of the power applied to the thermoelectric module 6100 from the polarity determination unit 6250. Alternatively, the reference voltage determination unit 6260 may receive the reference voltage from the outside. FIG. 7 illustrates that the reference voltage determination unit 6260 is connected to both the power supply unit 6210 and the polarity determination unit 6250 and also acquires an external input, but the present invention is not limited thereto, and the reference voltage determination unit 6260 may be connected to only one of the power supply unit 6210 and the polarity determination unit 6250 or may acquire information such as a power characteristic, a reference voltage, or the like only from one of the power supply unit 6210 and the polarity determination unit 6250.

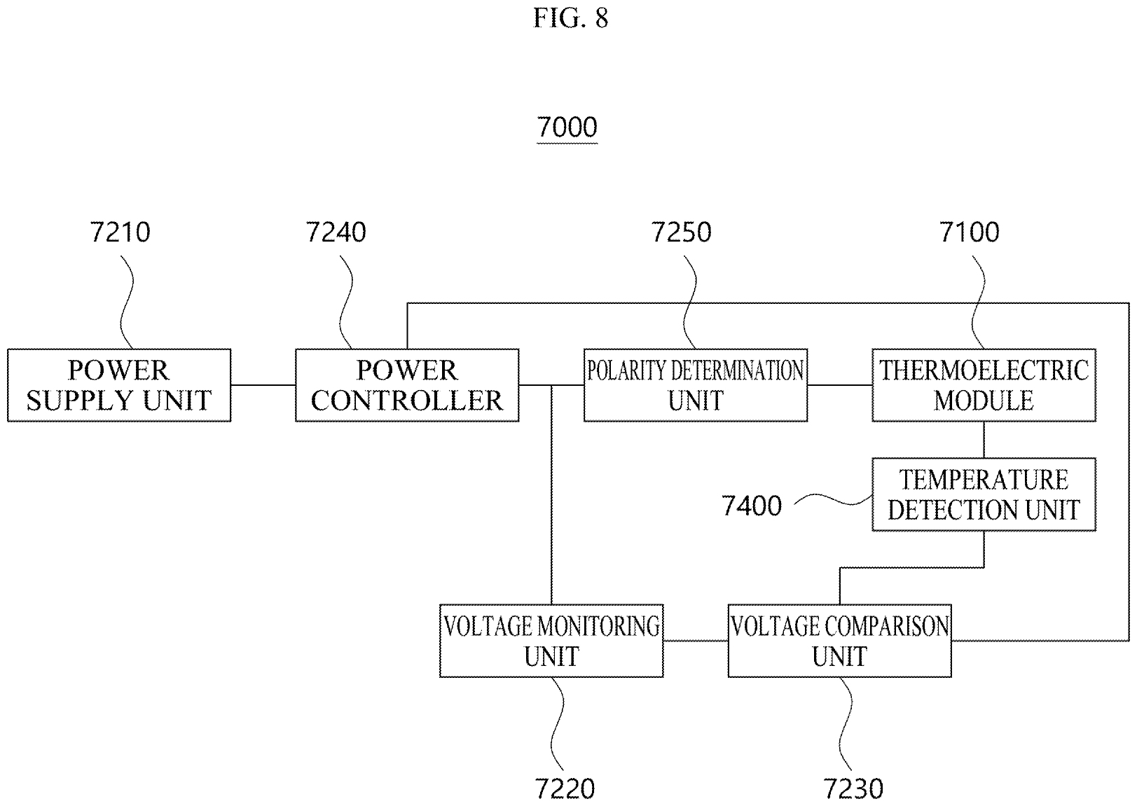

FIG. 8 is a view related to yet another example of the thermoelectric device according to one embodiment of the present specification. Referring to FIG. 8, a thermoelectric device 7000 according to one embodiment of the present specification may include a thermoelectric module 7100, a power supply unit 7210, a voltage monitoring unit 7220, a voltage comparison unit 7230, a power controller 7240, a polarity determination unit 7250, and a temperature detection unit 7400. In comparison with FIG. 5, FIG. 8 relates to the thermoelectric device 7000 further including the temperature detection unit 7400, and in order to avoid repeated description, the added content will be mainly described here. The temperature detection unit 7400 may detect a temperature of at least one region of the thermoelectric module 7100. The voltage comparison unit 7230 may acquire the temperature detected by the temperature detection unit 7400. The voltage comparison unit 7230 may output an application control signal based on the detected temperature and an output voltage of the thermoelectric module 7100. According to one embodiment, the voltage comparison unit 7230 may compare an appropriate voltage for each temperature with the detected temperature and the output voltage to output the application control signal. For example, when an appropriate voltage at a first temperature is a first voltage and the detected temperature is the first temperature, and when a difference between the output voltage and the first voltage is greater than or equal to a predetermined value, the voltage comparison unit 7230 may output the application control signal which instructs not to apply power to the thermoelectric module 7100.

Hereinafter, a temperature change of the thermoelectric device according to an embodiment of the present specification, a resistance change thereof and a reference voltage will be described.

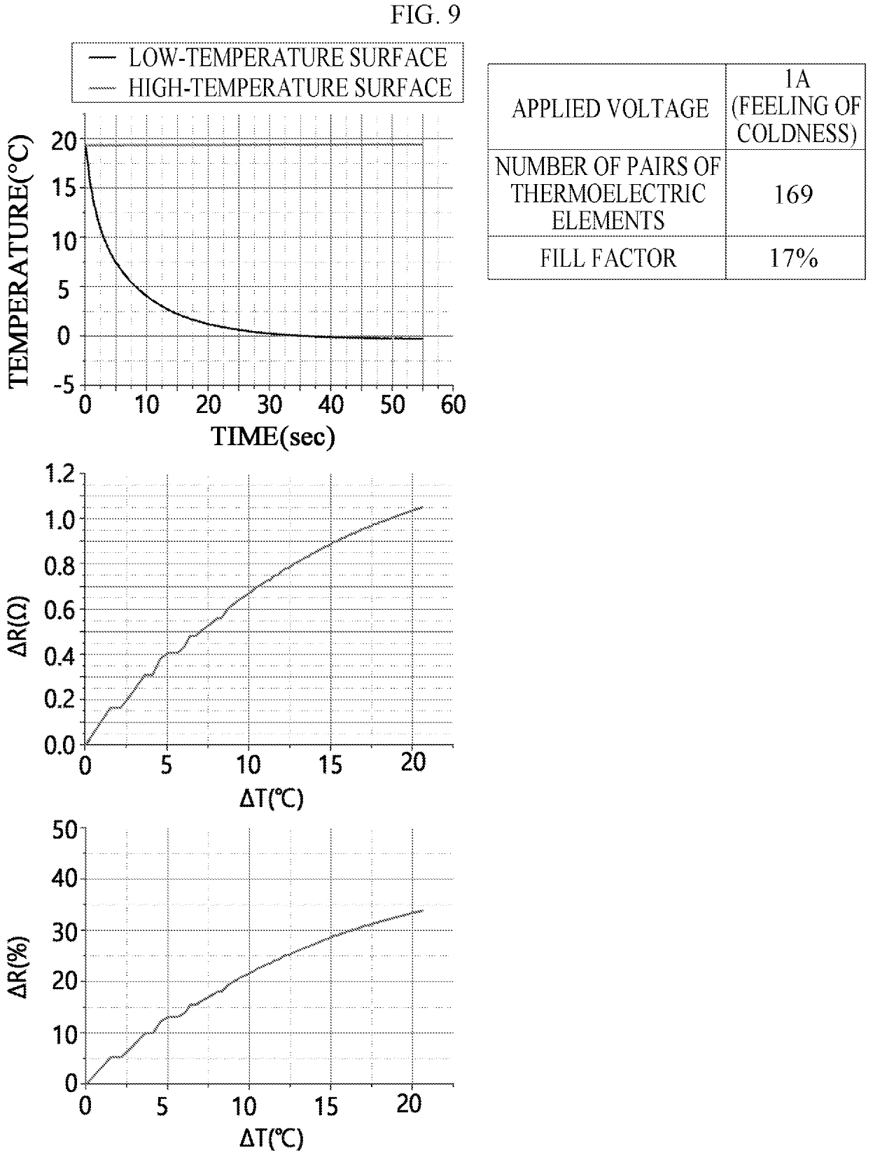

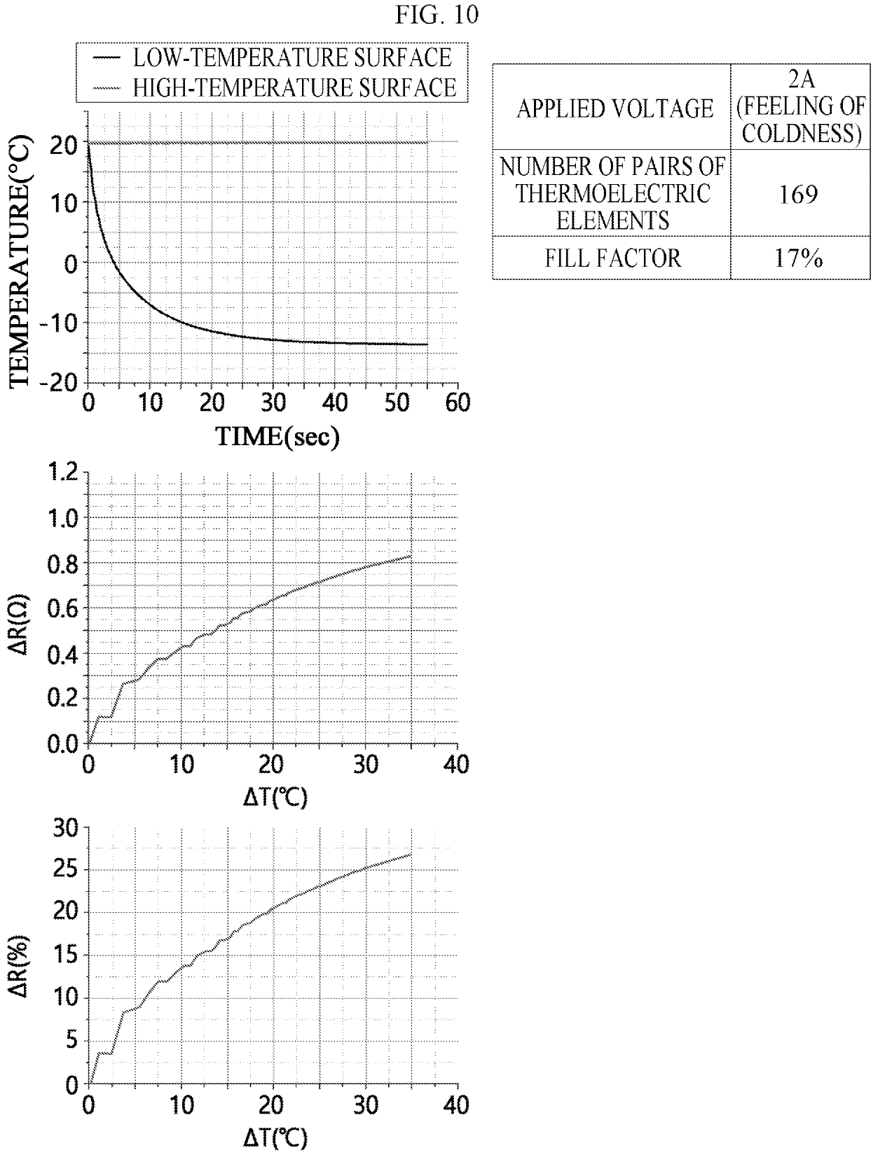

FIGS. 9 and 10 are graphs related to an example of a temperature change of the thermoelectric device according to one embodiment of the present specification. The graphs in FIGS. 9 and 10 relate to a thermoelectric device providing a feeling of coldness, and the thermoelectric device includes 169 pairs of thermoelectric elements and a fill factor is 17%. Data was measured in a state in which a low-temperature surface was exposed to the atmosphere and a high-temperature surface was in contact with a chiller to keep a temperature at 20° C. Further, a current of 1 A was applied to the thermoelectric module in FIG. 9 and a current of 2 A was applied to the thermoelectric module in FIG. 10. In FIGS. 9 and 10, the top graph indicates the temperature change according to time for the high-temperature surface and the low-temperature surface of the thermoelectric module, the middle graph indicates a resistance change of the thermoelectric module according to a temperature difference between the high-temperature surface and the low-temperature surface as a resistance value, and the bottom graph indicates the resistance change of the thermoelectric module according to the temperature difference between the high-temperature surface and the low-temperature surface as a ratio (ΔR (%)=ΔR/Rᵢₙᵢₜ).

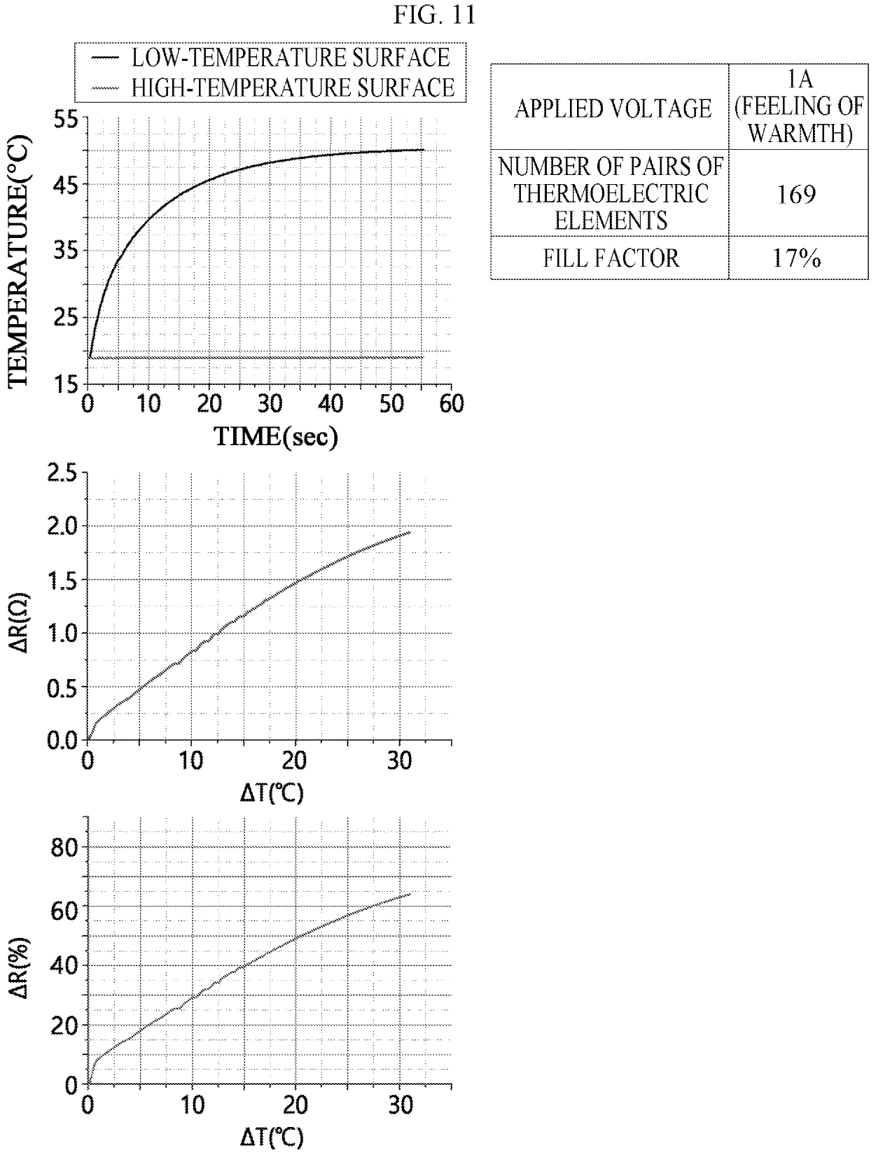

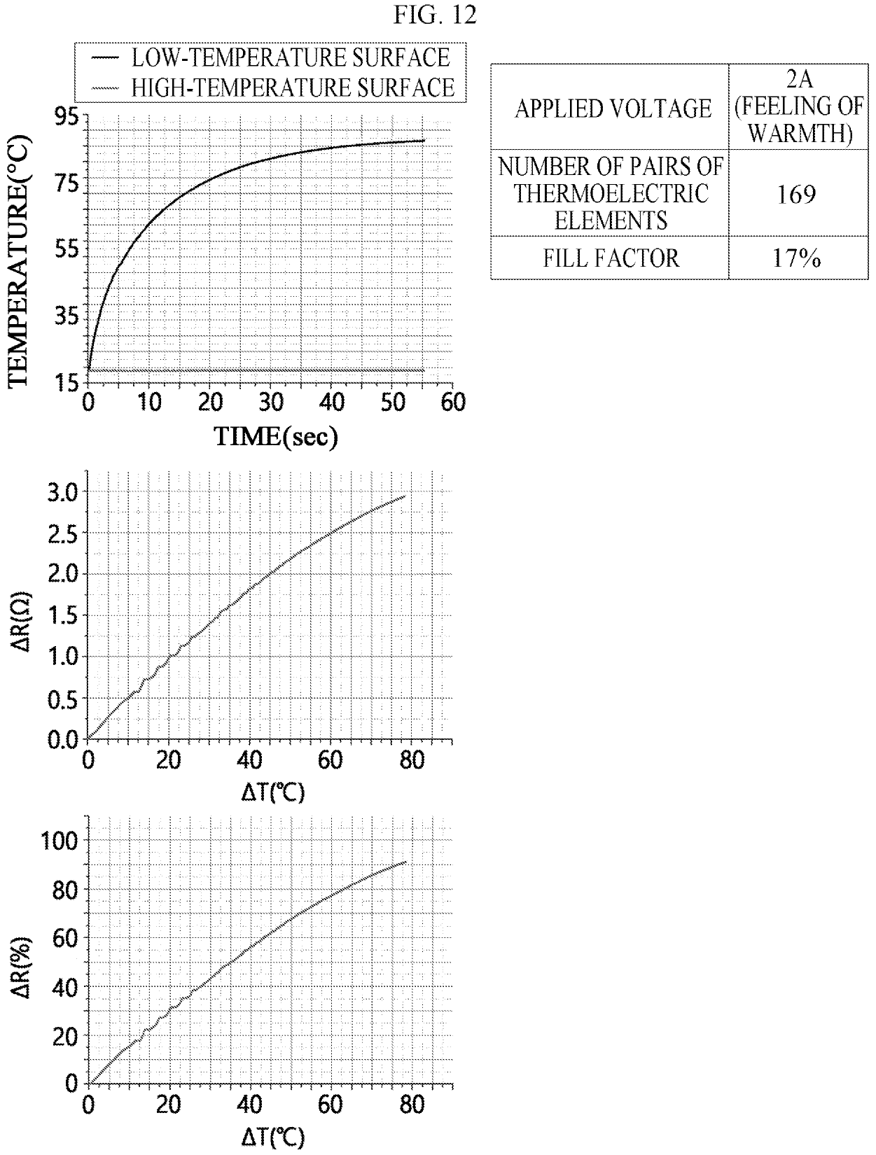

FIGS. 11 and 12 are graphs related to another example of the temperature change of the thermoelectric device according to one embodiment of the present specification. The graphs in FIGS. 11 and 12 relate to a thermoelectric device providing a feeling of warmth, and the thermoelectric device includes 169 pairs of thermoelectric elements and a fill factor is 17%. Data was measured in a state in which a high-temperature surface was exposed to the atmosphere and a low-temperature surface was in contact with a chiller to keep a temperature at 20° C. Further, a current of 1 A was applied to the thermoelectric module in FIG. 11 and a current of 2 A was applied to the thermoelectric module in FIG. 12. In FIGS. 11 and 12, the top graph indicates the temperature change according to time for the high-temperature surface and the low-temperature surface of the thermoelectric module, the middle graph indicates a resistance change of the thermoelectric module according to a temperature difference between the high-temperature surface and the low-temperature surface as a resistance value, and the bottom graph indicates the resistance change of the thermoelectric module according to the temperature difference between the high-temperature surface and the low-temperature surface as a ratio.

Referring to FIGS. 9 to 12, in both the cases of providing the feeling of coldness and the cases of providing the feeling of warmth, since the temperature difference occurred between the high-temperature surface and the low-temperature surface when power was applied to the thermoelectric module, the resistance of the thermoelectric module increased.

The resistance change of the thermoelectric module may become different according to the magnitude of power applied to the thermoelectric module or the intensity of the thermal stimulus provided by the thermoelectric module. For example, the resistance change according to a change in the temperature difference may increase as the magnitude of power applied to the thermoelectric module decreases. Referring to FIGS. 9 and 10, it can be seen that the resistance change is approximately 1.3 Ω 33% when the temperature difference is 20° C. in the case in which the feeling of coldness is provided by applying the current of 1 A, and thus is greater than the resistance change of approximately 0.64 Ω 21% in the case in which the feeling of coldness is provided by applying the current of 2 A. Referring to FIGS. 11 and 12, it can be seen that the resistance change is approximately 1.5 Ω 48.9% when the temperature difference is 20° C. in the case in which the feeling of warmth is provided by applying the current of 1 A, and thus is greater than the resistance change of approximately 1.0 Ω 31.5% in the case in which the feeling of warmth is provided by applying the current of 2 A.

Accordingly, the reference voltage may vary according to the magnitude of power applied to the thermoelectric module or the intensity of thermal stimulation provided by the thermoelectric module. For example, the reference voltage may increase as the magnitude of the current applied to the thermoelectric module decreases. Alternatively, a ratio of the reference voltage for an initial output voltage may increase as the magnitude of current applied to the thermoelectric module decreases. Here, the initial output voltage may be an output voltage of the thermoelectric module at a time point at which the operation of the thermoelectric device starts. Alternatively, the reference voltage may be determined based on the maximum magnitude of power applied to the thermoelectric module. For example, when the magnitude of power which may be applied to the thermoelectric module includes a first value and a second value greater than the first value, the reference voltage may be determined based on the second value. Of course, as described above, the reference voltage may be determined regardless of the magnitude of the power or the intensity of the thermal stimulus provided by the thermoelectric module.

The resistance change of the thermoelectric module may become different according to the polarity of power applied to the thermoelectric module or the type of thermal stimulus provided by the thermoelectric module. For example, the resistance change according to the change in the temperature difference may be larger in the case in which the thermoelectric module provides the feeling of warmth compared to the case in which the thermoelectric module provides the feeling of coldness. Referring to FIGS. 9 and 11, it can be seen that the resistance change is approximately 1.5 Ω 48.9% when the temperature difference is 20° C. in the case in which the feeling of warmth is provided by applying the current of 1 A, and thus is greater than the resistance change of approximately 1.3 Ω 33% in the case in which the feeling of coldness is provided. Referring to FIGS. 10 and 12, it can be seen that the resistance change is approximately 1.0 Ω 31.5% when the temperature difference is 20° C. in the case in which the feeling of warmth is provided by applying the current of 2 A, and thus is greater than the resistance change of approximately 0.64 Ω 21% in the case in which the feeling of coldness is provided.

Accordingly, the reference voltage may vary according to the polarity of power applied to the thermoelectric module or the type of thermal stimulus provided by the thermoelectric module. For example, the reference voltage in the case in which the thermoelectric module provides the feeling of warmth may be larger than the reference voltage in the case in which the thermoelectric module provides the feeling of coldness. Alternatively, a ratio of the reference voltage for the initial output voltage in the case in which the thermoelectric module provides the feeling of warmth may be larger than a ratio of the reference voltage for the initial output voltage in the case in which the thermoelectric module provides the feeling of coldness. Of course, as described above, the reference voltage may be determined regardless of the polarity of power applied to the thermoelectric module or the type of thermal stimulus provided by the thermoelectric module. In this case, since the resistance change may be larger in the case in which the thermoelectric module provides the feeling of warmth compared to the case in which the thermoelectric module provides the feeling of coldness, the reference voltage may be determined with respect to the thermoelectric module providing the feeling of warmth, but is not limited thereto.

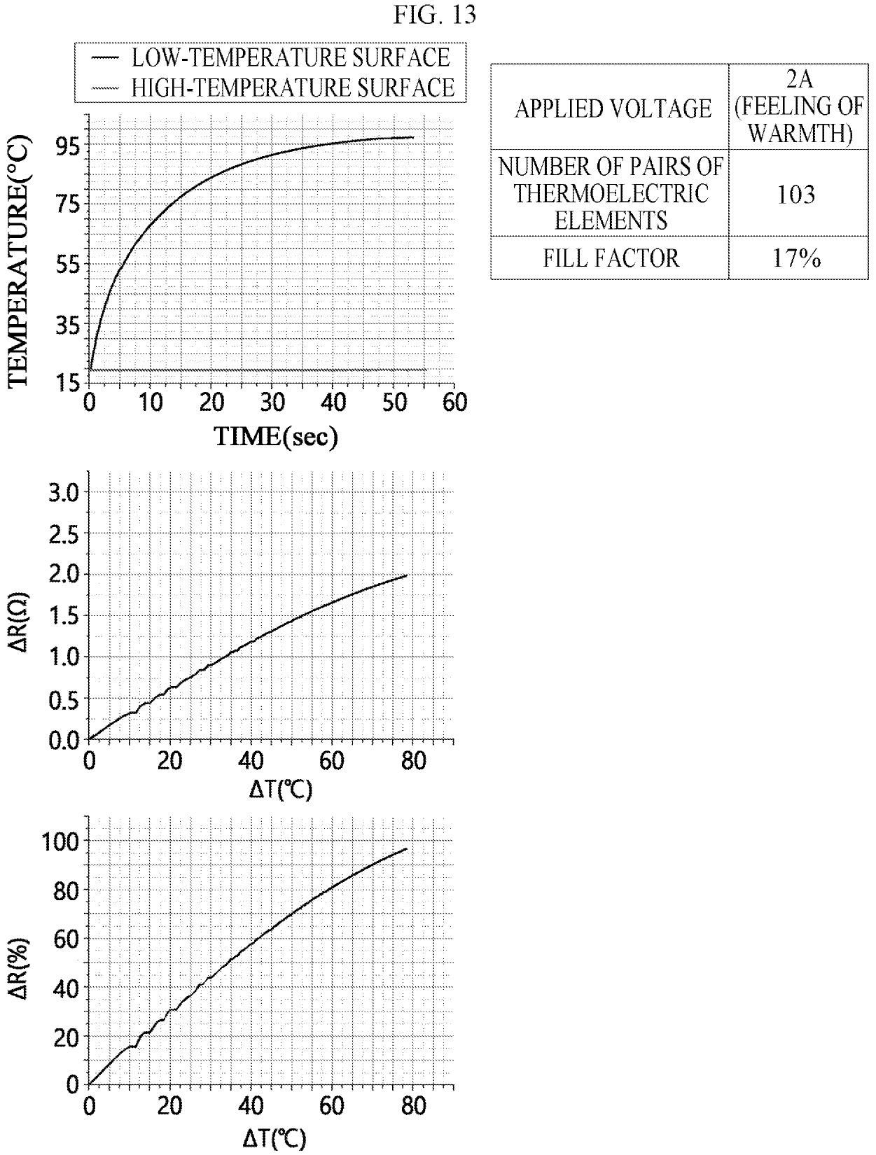

FIG. 13 is a graph related to still another example of the temperature change of the thermoelectric device according to one embodiment of the present specification. The graph in FIG. 13 relates to a thermoelectric device providing a feeling of warmth, and relates to a thermoelectric device in which only the number of thermoelectric element pairs is changed from 169 to 103 compared to FIG. 12.

Changes in resistance value of the thermoelectric module may become different according to the number of thermoelectric elements. For example, the change in the resistance value may increase as the number of thermoelectric elements increases. Comparing FIGS. 12 and 13, in a measured temperature section, it can be seen that a change ΔR(Ω) in the resistance value of the thermoelectric module in FIG. 12 including 169 pairs of thermoelectric elements is larger than a change ΔR(Ω) in the resistance value of the thermoelectric module in FIG. 13 including 103 pairs of thermoelectric elements.

On the other hand, the ratios of the resistance change of the thermoelectric module may be the same or similar according to the number of thermoelectric elements. Comparing FIGS. 12 and 13, it can be seen that the ratios ΔR (%) of the resistance change in the measured temperature change section are similar.

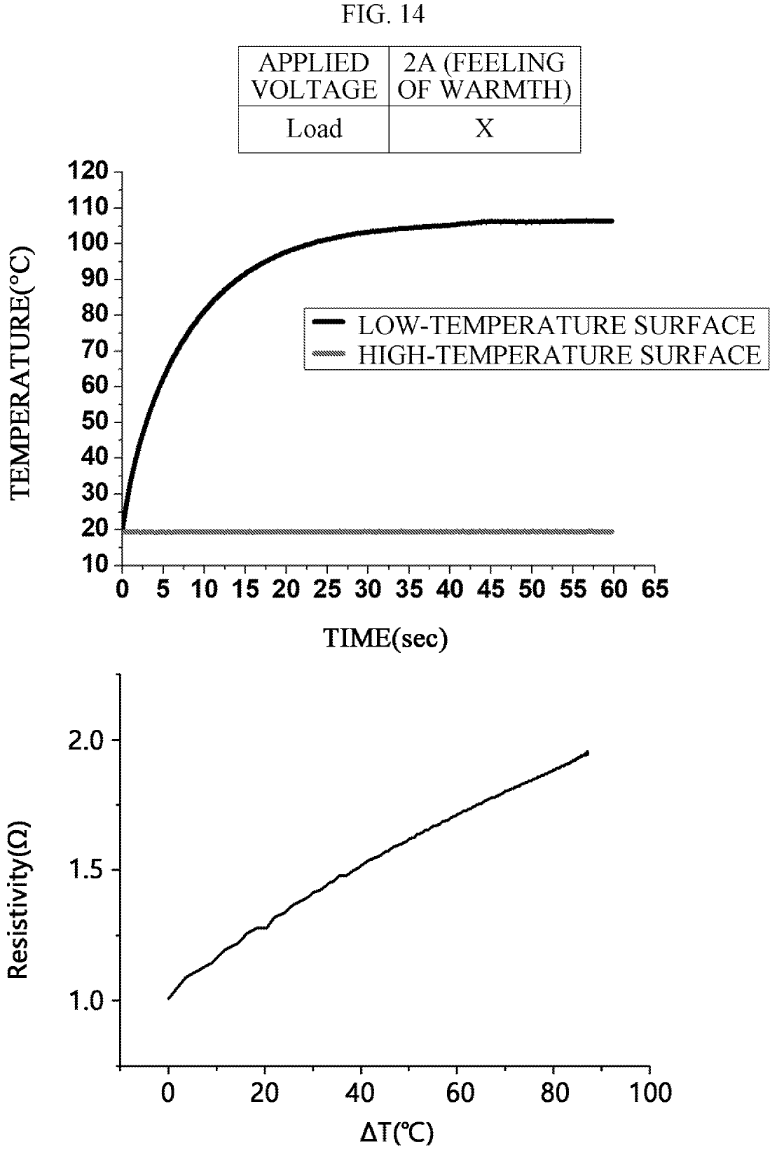

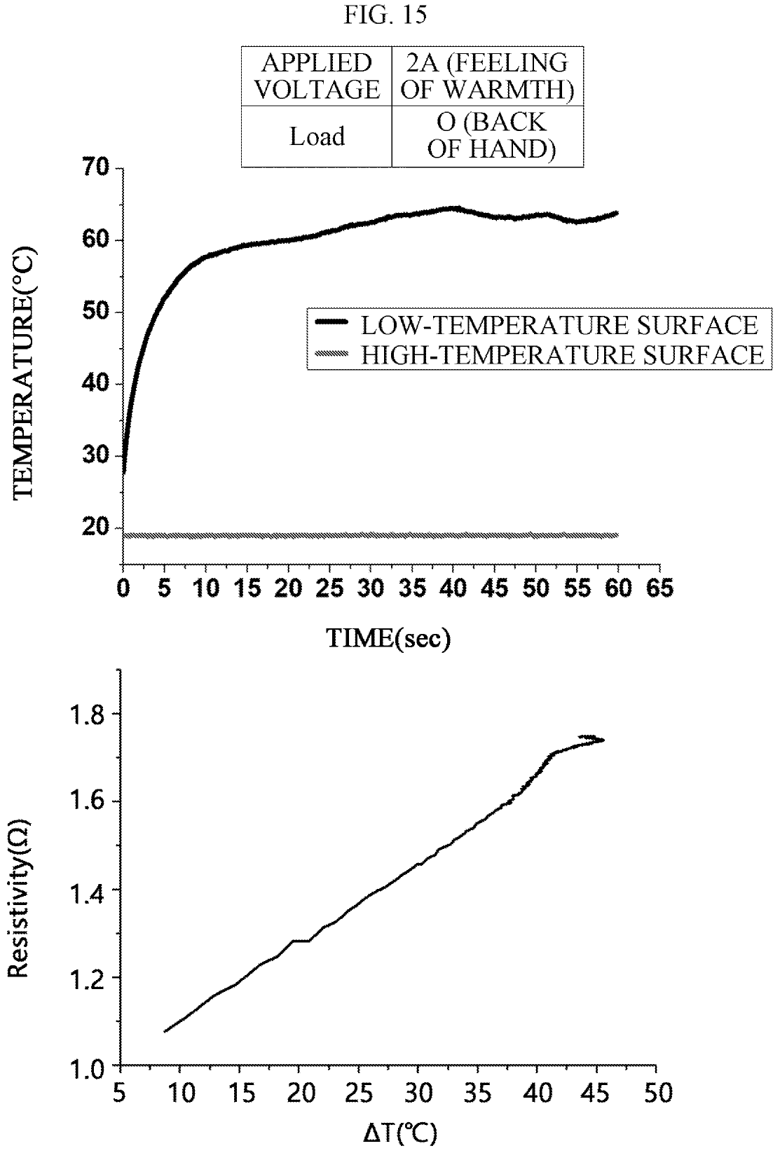

FIGS. 14 and 15 are graphs related to yet another example of the temperature change of the thermoelectric device according to one embodiment of the present specification. The graphs in FIGS. 14 and 15 relate to a thermoelectric device providing a feeling of warmth, and a current of 2 A was applied to the thermoelectric module. Data was measured in a state in which a high-temperature surface was exposed to the atmosphere in FIG. 14, and in a state in which a low-temperature surface was in contact with a back of a user's hand in FIG. 15. Further, in both FIGS. 14 and 15, the data was measured in a state in which the low-temperature surface was in contact with a chiller to keep a temperature at 20° C. In FIGS. 14 and 15, the top graph indicates the temperature change according to time for the high-temperature surface and the low-temperature surface of the thermoelectric module, and the bottom graph indicates the resistance change of the thermoelectric module according to a temperature difference between the high-temperature surface and the low-temperature surface.

The temperature of the thermoelectric module may vary according to whether the thermoelectric module is in contact with the user or whether the user is wearing the thermoelectric device. Comparing FIGS. 14 and 15, it can be seen that the temperature of the high-temperature surface increases by 100° C. or more when the high-temperature surface is exposed to the atmosphere, but the temperature of the high-temperature surface converges at approximately 60° C. when the high-temperature surface is in contact with the back of the user's hand. Further, the resistance of the thermoelectric module increases to approximately 1.9Ω when the user is not wearing the thermoelectric device, but the resistance of the thermoelectric module increases to approximately 1.7Ω when the user is wearing the thermoelectric device. Accordingly, since the output voltage of the thermoelectric module will also appear higher when the user is not wearing the thermoelectric device, it is possible to provide a thermoelectric device in which the thermoelectric module does not operate in the case in which the user is not wearing the thermoelectric device when power supply to the thermoelectric module is stopped in the case in which the output voltage is greater than or equal to the reference voltage as the reference voltage is appropriately determined.

In the above, monitoring the voltage between two points of the thermoelectric module according to the embodiment of the present specification has been mainly described, but the voltage between three or more arbitrary points of the thermoelectric module may also be monitored.

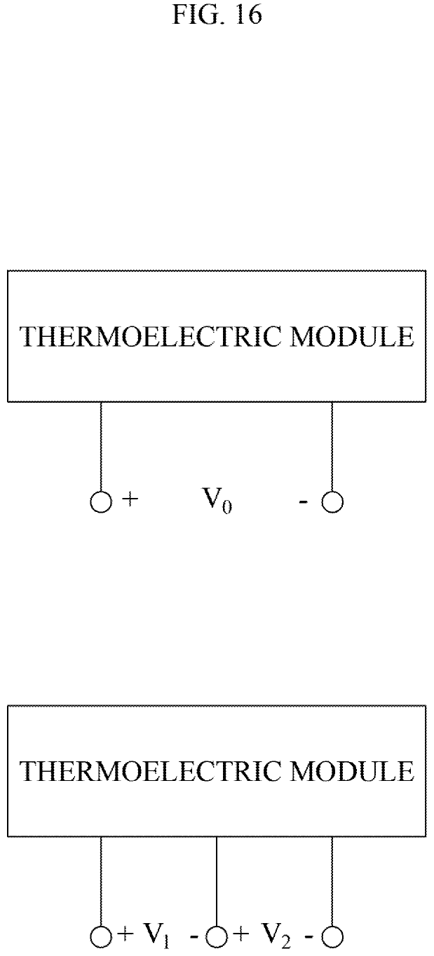

FIG. 16 is a view related to a thermoelectric module including a plurality of terminals according to one embodiment of the present specification. Referring to FIG. 16, the top drawing relates to a thermoelectric module including two terminals and a voltage V₀ between the two terminals, and the bottom drawing relates to a thermoelectric module including three terminals and voltages V₁ and V₂ between the three terminals.

In the case of monitoring the voltage between three or more terminals, a broken region due to a crack or the like in the thermoelectric module may be detected. Referring to FIG. 16, the broken region in the thermoelectric module may be detected based on the first voltage V₁ between the first terminal and the second terminal and the second voltage V₂ between the second terminal and the third terminal. For example, when the difference between the first voltage and the second voltage is greater than or equal to a predetermined reference value, it may be determined that one region among a first region of the thermoelectric module corresponding to the first terminal and the second terminal and a second region corresponding to the second terminal and the third terminal is broken. Here, the reference value may be determined in consideration of various conditions similar to the above-described reference voltage. For example, the reference value may be determined based on at least one among the characteristic of power applied to the thermoelectric module, the number of thermoelectric element in the thermoelectric module, and the fill factor of the thermoelectric module.

The configuration and features of the present invention have been described above with respect to the embodiments, but the present invention is not limited thereto, and it is apparent that those skilled in the art may perform various changes or modifications within the spirit and scope of the present invention, and accordingly, it is noted that these changes or modifications belong to the accompanying claims.

1. A thermoelectric device including:
a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor,
a power supply unit configured to output a predetermined current applied to the thermoelectric module to cause the thermoelectric module to perform a thermoelectric operation including an endothermic operation and an exothermic operation so that the thermal stimulus is provided through the first surface,
a voltage monitoring unit configured to monitor an output voltage of the thermoelectric module, wherein the output voltage reflects a temperature difference between the first surface and the second surface,
a voltage comparison unit configured to compare the output voltage and a reference voltage, and output an application control signal which instructs whether to apply power to the thermoelectric module to stop supplying the power to the thermoelectric module when the temperature difference is greater than or equal to a threshold value, and
a power controller configured to adjust whether to apply the power to the thermoelectric module based on the application control signal.

2. The thermoelectric device of claim 1, wherein the thermoelectric module further includes a support layer disposed between the thermoelectric element to support the thermoelectric element while allowing deformation of the thermoelectric module.

3. The thermoelectric device of claim 1, wherein the voltage comparison unit is configured to output a first application control signal which instructs not to apply power to the thermoelectric module when the output voltage is greater than or equal to the reference voltage, and
the power controller is configured to cut off the power supplied to the thermoelectric module when the first application control signal is input.

4. The thermoelectric device of claim 2, wherein the voltage comparison unit is configured to output a second application control signal which instructs to apply power to the thermoelectric module when the output voltage is lower than the reference voltage, and
the power controller is configured to allow the power to be supplied to the thermoelectric module when the second application control signal is input.

5. The thermoelectric device of claim 1, wherein the power supply unit is configured to output a predetermined current applied to the thermoelectric module based on a resistance of the thermoelectric module to apply a pre-determined current to the thermoelectric module.

6. The thermoelectric device of claim 1, wherein the voltage monitoring unit includes a resistor, and is configured to acquire the output voltage based on a voltage applied to the resistor.

7. The thermoelectric device of claim 1, wherein the voltage comparison unit includes a comparator.

8. The thermoelectric device of claim 1, wherein the power controller includes a transistor.

9. The thermoelectric device of claim 1, wherein the thermoelectric module further includes a polarity determination unit configured to determine a polarity of the power input to the thermoelectric module so that the thermoelectric module performs the endothermic operation or the exothermic operation.

10. The thermoelectric device of claim 9, wherein the polarity determination unit is configured to include an H-bridge circuit.

11. The thermoelectric device of claim 1, wherein the reference voltage is determined based on at least one of the number of N-type semiconductors and P-type semiconductors, intensity of the thermoelectric operation, a type of the thermoelectric operation, and a fill factor corresponding to an area occupied by the N-type semiconductors and the P-type semiconductors on the first surface.

12. The thermoelectric device of claim 1, wherein the thermoelectric operation includes a first thermoelectric operation and a second thermoelectric operation having the same type but having different intensity from the first thermoelectric operation, and the reference voltage includes a first reference voltage corresponding to the first thermoelectric operation and a second reference voltage corresponding to the second thermoelectric operation and different from the first reference voltage.

13. The thermoelectric device of claim 1,
wherein, when the thermoelectric module performs the exothermic operation, the reference voltage is the first reference voltage, and,
wherein, when the thermoelectric module performs the endothermic operation, the reference voltage is the second reference voltage different from the first reference voltage.

14. A thermoelectric device including:
a thermoelectric module having a first surface providing a thermal stimulus to a user and a second surface opposite to the first surface, and including an N-type semiconductor and a P-type semiconductor disposed between the first surface and the second surface and an electrode configured to electrically connect the N-type semiconductor and the P-type semiconductor, and
a control module configured to control power supplied to the thermoelectric module,
wherein the control module configured to:
output a predetermined current applied to the thermoelectric module to cause the thermoelectric module to perform a thermoelectric operation including an endothermic operation and an exothermic operation so that the thermal stimulus is provided through the first surface,
monitor an output voltage of the thermoelectric module, wherein the output voltage reflects a temperature difference between the first surface and the second surface, compares the output voltage and a reference voltage,
output an application control signal which instructs whether to apply the power to the thermoelectric module to stop supplying the power to the thermoelectric module when the temperature difference is greater than or equal to a threshold value, and
adjust whether to apply the power to the thermoelectric module based on the application control signal.

15. A thermoelectric device including:
a thermoelectric module having a first surface providing a thermal stimulus to a user and a second surface to opposite the first surface, and including an N-type semiconductor and a P-type semiconductor disposed between the first surface and the second surface and an electrode configured to electrically connect the N-type semiconductor and the P-type semiconductor, and
a control module configured to control power supplied to the thermoelectric module,
wherein the control module configured to
output a predetermined current applied to the thermoelectric module to cause the thermoelectric module to perform a thermoelectric operation including an endothermic operation and an exothermic operation so that the thermal stimulus is provided through the first surface,
monitor an output voltage of the thermoelectric module, and
adjust whether to apply the power to the thermoelectric module by comparing the output voltage and a reference voltage.
